(19) United States
(12) Patent Application Publication
(10) Pub. No.: US 2003/0075036 A1
(43) Pub. Date: Apr. 24, 2003

(54) Electronic music apparatus that enables user to purchase music related product from server

(76) Inventors: Yoshimasa Isozaki, Hamakita-shi (JP); Yutaka Hasegawa, Hamamatsu-shi (JP)

Correspondence Address: HARNESS, DICKEY & PIERCE, P.L.C., P.O. BOX 828, BLOOMFIELD HILLS, MI, 48303, US

(21) Appl. No.: 10/234,860

(22) Filed: Sep. 4, 2002

(30) Foreign Application Priority Data
Sep. 4, 2001 (JP) 2001-266854

(51) Int. Cl. G11C 5/00

(52) U.S. Cl. 84/602; 84/601

(57) ABSTRACT

An electronic music apparatus comprises a storage device that stores music data comprising music related data that is information for accessing to a music related product sales site on a network, a reading device that reads the music related data from the music data, an accessing device that accesses to the music related product sales site in accordance with the read music related data, and a transmitter that transmits a request for purchasing a music related product to the music related product sales site. The music related product can be easily purchased.

### CROSS REFERENCE TO RELATED APPLICATION

This application is based on Japanese Patent Application 2001-266854, filed on Sep. 4, 2001, the entire product of which are incorporated herein by reference.

### BACKGROUND OF THE INVENTION

A) Field of the Invention

This invention relates to an electronic music apparatus and a product providing server, and more in detail, relates to a product providing server that sells a music related product and an electronic music apparatus that enables a user to purchase the music related product from the server.

B) Description of the Related Art

A personal computer and an electronic musical instrument or the like can store and reproduce music data such as MIDI data, audio data, etc. Also, a mobile information terminal such as a cellular phone or the like can store music data such as a ringer melody, karaoke data or the like which is formed based on a simplified MIDI standard or the like for the mobile information terminal and is reproduced as a ring tone or for karaoke.

A user of the above-described personal computer, the electronic musical instrument or a mobile information terminal may want to purchase products related to these music data. For example, purchasing (downloading) an electronic music score representing the music data may be considered. Also, for example, in the case when the music data is MIDI data, purchasing (downloading) audio data of a same music may be considered. Further, for example, the case of purchasing the music data related product and requesting a physical delivery of that might be considered.

Normally, in the case of purchasing a product related to music data on a sales site, for example, on the Internet or the like, a music data related product sales site should be found out by referring to a search engine or the like.

Also after accessing to the sales site, the music data related product is necessary be found out by searching in the site again.

### SUMMARY OF THE INVENTION

It is an object of the present invention to provide an electronic music device wherein a music related product is easy to be purchased.

It is another object of the present invention to provide a product providing server to sell music related products.

According to one aspect of the present invention, there is provided an electronic music apparatus comprising a storage device that stores music data comprising music related data that is information for accessing to a music related product sales site on a network, a reading device that reads the music related data from the music data, an accessing device that accesses to the music related product sales site in accordance with the read music related data, and a transmitter that transmits a request for purchasing a music related product to the music related product sales site.

According to another aspect of the present invention, there is provided an electronic music apparatus comprising a storage device that stores music data comprising search information for searching a music related product, a reading device that reads the searching information from the music data, a first transmitter that transmits the read searching information to a music related product sales site on a network, the music related product sales site replying a search result by searching a music related product in accordance with the searching information, and a second transmitter that transmits a request for purchasing the searched music related product.

### BRIEF DESCRIPTION OF THE DRAWINGS

FIG. 1 is a block diagram showing an example of a music related product purchasing system 100 according to an embodiment of the present invention.

FIG. 2 is a block diagram showing a hardware structure of an electronic musical instrument 3a (and a client PC3b) according to the embodiment of the present invention.

FIG. 3 is a block diagram showing a hardware structure of a mobile information terminal 3c according to the embodiment of the present invention.

FIG. 4 are concept diagrams showing formats of music data MD according to the embodiment of the present invention.

FIG. 5 is a flow chart showing a first example of purchasing and sales operations of a music related product according to the embodiment of the present invention performed by an electronic music device 3 and a product providing server.

FIG. 6 is a flow chart showing a second example of purchasing and sales operations of a music related product according to the embodiment of the present invention performed by an electronic music device 3 and a product providing server.

FIG. 7 is a flow chart showing a first example of purchasing and search and sales operations of a music related product according to the embodiment of the present invention performed by an electronic music device 3 and a product providing server.

FIG. 8 is a flow chart showing a second example of purchasing and search and sales operations of a music related product according to the embodiment of the present invention performed by an electronic music device 3 and a product providing server.

### DETAILED DESCRIPTION OF THE PREFERRED EMBODIMENTS

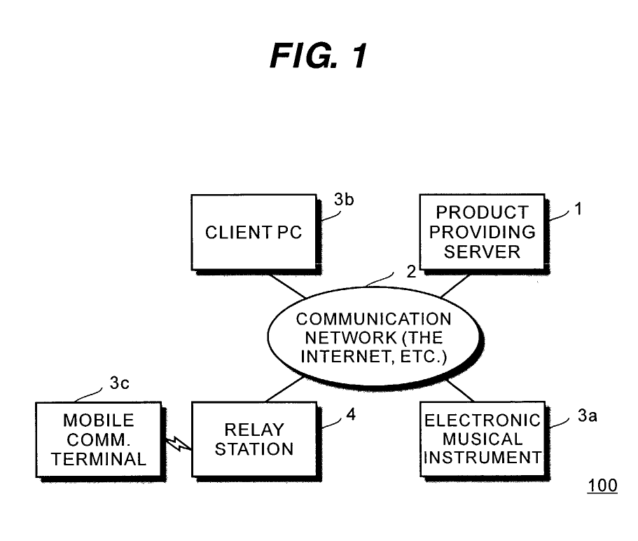

FIG. 1 a block diagram showing an example of a music related product purchasing system 100 according to an embodiment of the present invention. The music related product purchasing system 100 is consisted of, for example, a product providing server 1, a communication network 2 such as the Internet, an electronic music device 3 such as an electronic musical instrument 3a, a client PC3b and a mobile information terminal 3c, and a relay station 4.

The product providing server 1 is, for example, the World Wide Web (WWW) server on the Internet, and responses to various kinds of requests from the connected clients and provides various kinds of information.

The electronic music device 3 stores at least one music data to which information for accessing to a music related product sales site (a product providing server 1) is embedded. Also, in the case that the electronic music device 3 is the mobile information terminal 3c, it is connected to a communication network via a relay station 4. The relay station 4 is, for example, a carrier of a cellular phone or the like, and relays a communication with the communication network 2 by transmitting and receiving a wireless communication to/from the mobile information terminal 3c.

The product providing server 1 records a sales page of a product related to particular music data (a product related to music data) and a Uniform Resource Locator (URL) of the sales page, and transmits the sales page or the URL of the sales page to the electronic music device 3 in accordance with the request from the electronic music device 3 that is connected via the communication network 2. In the product server 1, a product related to music data that can be provided via the communication network 2 is stored. The product related to music data is a downloadable product, for example an electronic score corresponding to particular music data, MIDI data, audio data and electronic lyrics data or the like. Also the product related to music data is a physical product, for example, a paper score (a hard copy of a music score) corresponding to particular music data, a lyrics card, a book such as a related magazine and a storage medium storing the music data or the like. When purchasing the physical product is requested, the product providing server 1 executes a process to deliver the physical product physically. Further, a video tape and a DVD of a movie and a drama which the music represented by the music data is used, the product of TV commercial film in which the music is used, a concert ticket and the related goods of the artist of the music and a instrument used in the music are considered to be the physical product.

When a user send a music related product obtaining instruction from the electronic music device 3 storing music data, the electronic music device 3 connects to the product providing server 1 via the communication network 2 in accordance with the information for accessing to the music related product sales site (the product providing server 1) embedded in the music data.

The above-described music related product purchasing system 100 enables the user to easily purchase the music related product by the information embedded in the music data. For example, in the case that the music data is the MIDI data, the user can purchase (download) the audio data of the same music represented by the music data. Also, for example, the user can purchase a lyrics card or the like of the music data and make it deliver to the user's home or the like physically.

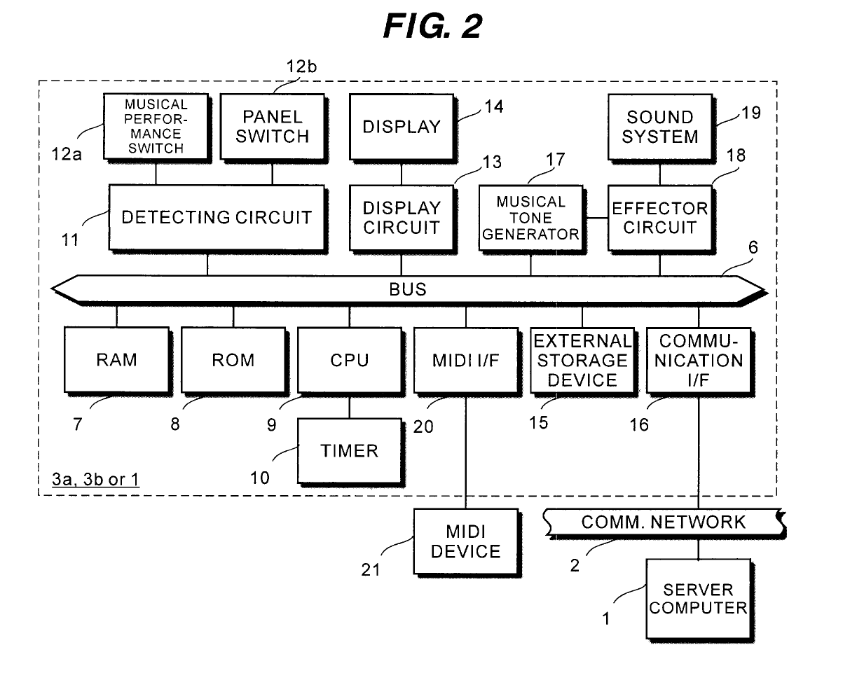

FIG. 2 is a block diagram showing a hardware structure of an electronic musical instrument 3a (and a client PC3b) according to the embodiment of the present invention. The product providing server 1 also has an almost same structure as this electronic musical instrument 3a.

The electronic musical instrument 3a (and the client PC3b) is formed of a bus 6, a RAM 7, a ROM 8, a CPU 9, a timer 10, a detector circuit 11, a musical performance switch 12a, a panel switch 12b, a display circuit 13, a display 14, an external storage device 15, a communication interface 16, a musical tone generator 17, an effecter circuit 18, a sound system 19 and MIDI interface 20.

The RAM 7, the ROM 8, the CPU 9, the detector circuit 11, the display circuit 13, the external storage device 15, the communication interface 16, the musical tone generator 17, the effecter circuit 18 and the MIDI interface 20 are connected to the bus 6.

The RAM 7 has a working area of the CPU 9, works as a register or a buffer, and stores various kinds of flags, parameters or the like. The ROM 8 can store a various kinds of parameters and a controlling program, or a program for realizing the embodiment of the present invention.

The CPU 9 performs a calculation or a control in accordance with a controlling program or the like stored in the ROM 8 or the external storage device 15. The timer 10 is connected to the CPU 9 and provides a basic clock signal and interrupt timing or the like to the CPU 9.

The musical performance switch 12a such as a musical keyboard is connected to the detector circuit 11 and provides a musical performance signal based on a musical performance by the user.

The user can input various kinds of information and perform various kinds of set up by using the panel switch 12b that has a plurality of switches connected to the detector circuit 11. For example, the electronic musical device 3 of the embodiment of the present invention equips a score switch for accessing to the sales page of the electronic score or the paper score, an audio switch for accessing to the sales page of the audio data and a MIDI switch for accessing to the sales page of the MIDI data or the like. For example, when the user wants to access to a purchasing page of an electronic score corresponds to currently loaded music data, the user operates the score switch. Also a book switch and a lyrics card switch or the like may be equipped.

Anything that can output a signal corresponding to an input by the user may be used as a panel switch 12b, for example, a keyboard for a text input, a mouse, a rotary encoder, a switch, a pad, a fader, a slider, a keyboard for a musical performance, a joystick and a jog-shuttle or the like can be used as the panel switch 12b. Also the panel switch 12b may be a soft switch or the like displayed on the display 14, which is operated with the mouse and other switch or the like.

The display circuit 13 is connected to the display 14 and can display various kinds of information on the display 14. The user inputs a various kinds of information and performs a various kinds of set ups by referring to the information displayed on this display 14. On the display 14, information related to the music data, the score and the music data related product sales page can be displayed. Also, the display 14 may be formed by connecting with an external display device. Also a touch panel can be used for the display 14. In this case, an instruction of the user can be input by the user manipulating the switch or the like displayed on the display 14, therefore it doubles as the function of the panel switch 12b.

The external storage device 15 contains an interface for an external storage device, and is connected to the bus 6 via the interface. The external storage device 15 is, for example, a floppy (a registered trademark) disk drive (FDD), a hard disk drive (HDD), a magnet-optical disk (MO) drives, a compact disk read only memory (a CD-ROM) drive, a Digital Versatile Disc (DVD) drive and a semiconductor memory or the like. In the external storage device 15, a later-described music data according to the embodiment of the present invention, various kinds of parameters and data and a program for realizing the embodiment of the present invention or the like can be stored.

The communication interface 16 can be connected to a communication network 2 such as a local area network (LAN), the Internet and a telephone line or the like, and makes a connection with a server computer (the product providing sever 1) via the communication network 2. Therefore, an electronic score data, a web page data for a music related product sales, a controlling program, a program for realizing the embodiment of the present invention and music data according to the embodiment of the present invention can be downloaded to the external storage device 15 such as the HDD, the RAM 7 or the like from the server computer. Further, the communication interface 16 and communication network 2 are not limited to be a wired communication system, but also be a wireless communication system. Both wired and wireless communication I/F may be equipped.

The musical tone generator 17 is a wave-memory type, a FM type, or the like and generates a musical tone signal in accordance with the music data such as sequence data stored in the external storage device 15 or a musical performance signal, a MIDI signal or the like provided from the musical performance switch 2a or the MIDI device 21 connected to the MIDI interface 20. The generated musical tone signal is supplied to the sound system 19 via the effecter circuit 17.

The effecter circuit 18 adds various kinds of effects to a digital musical tone signal supplied from the musical tone generator 17.

The sound system 19 contains a digital to analog (D/A) converter and a loud speaker, converts the digital musical tone signal to an analog musical tone signal and reproduces it from the loud speaker.

The MIDI interface (MIDI I/F) 20 is an interface that can be connected with an electronic musical instrument, other musical instrument, an audio device and a computer or the like. The MIDI I/F can at least transmit and receive a MIDI signal. The MIDI device 21 is an audio device, a musical instrument or the like connected to the MIDI interface 20. Also the MIDI device 21 can be used as a switch for inputting various kinds of data and set-ups other than the musical performance information.

Further, when it is used as the product providing sever 1, the music performance switch 12a, the musical tone generator 17, the effecter circuit 18, the sound system 19 and the MIDI interface 20 may be omitted.

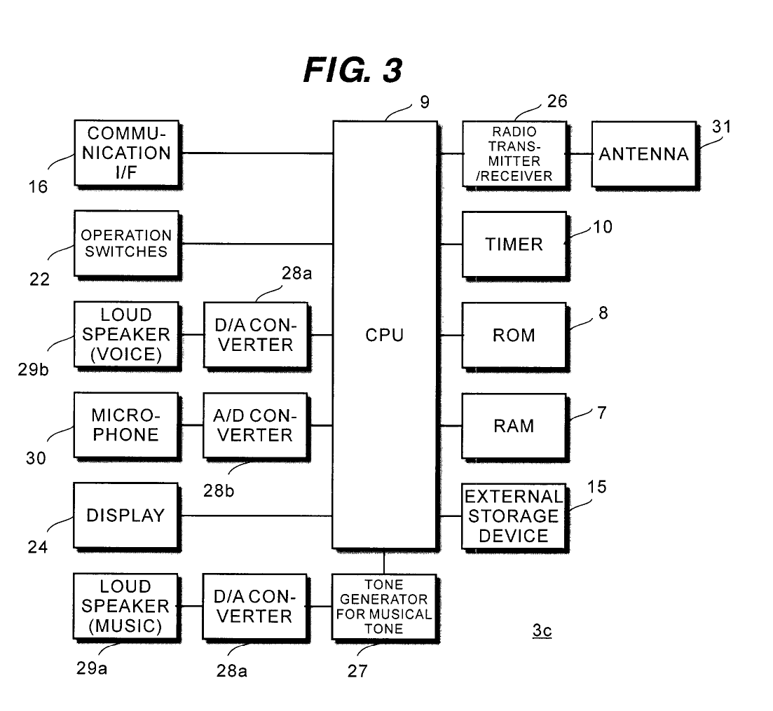

FIG. 3 is a block diagram showing a hardware structure of the mobile information terminal 3c according to the embodiment of the present invention.

The mobile information terminal 3c is consisted of a RAM 7, a ROM 8, a CPU 9, a timer 10, an external storage device 15, a communication interface 16, a group of operation switches 22, a display 24, a radio transmitter/receiver 26, a tone generator 27 for a musical tone, a D/A converter 28a, an A/D converter 28b, a loud speaker 29a for a musical tone, a loud speaker 29b for voice, a microphone 30, and an antenna 31.

The RAM 7, the ROM 8, the CPU 9, the timer 10, the external storage device 15 and the communication interface 16 in the above have almost the same structures as those of the electronic musical instrument 3a shown in FIG. 2, and therefore the explanations for those are omitted.

The group of operation switches 22 is used by a user to input various kinds of information and various kinds of set ups. The display 24 displays information related to the music data, the score and the music data related product sales page or the like.

When the mobile information terminal 3c is used as a telephone, the user dials by manipulating the group of operation switches 22 and inputs/outputs voice via the microphone 30 or the voice speaker 29b.

The voice input from the microphone 30 is converted from an analog audio signal to digital audio data in the A/D converter 28b and is sent to the relay station 4 (FIG. 1) via the radio transmitter/receiver 26 and the antenna 31. Also, the digital audio data transmitted from the relay station 4 is received in the radio transmitter/receiver 26 via the antenna 31 and converted to the analog audio signal in the D/A converter 28a to reproduce a voice tone from the voice speaker 29b.

When the mobile information terminal 3c is used as an information terminal, that is, in the case when the music date related product is purchased by connecting to the product providing server 1 (FIG. 1) according to the embodiment of the present invention or the like, the user accesses to the product providing server in accordance with the music data related information or the like embedded in a later-described music data by manipulating the group of switches 22. For example, when the electronic score is purchased, the score is displayed on the display 24.

The tone generator 27 for a musical tone, in the case of playing back the music data or the like, reads the music data from the ROM 8 or the external storage device 15 such as the semiconductor memory and generates a musical tone signal to be provided to the voice speaker 29a via the D/A converter 28a. The tone generator 27 for a musical tone is a wave memory type or an FM type, and an effecter circuit may be included.

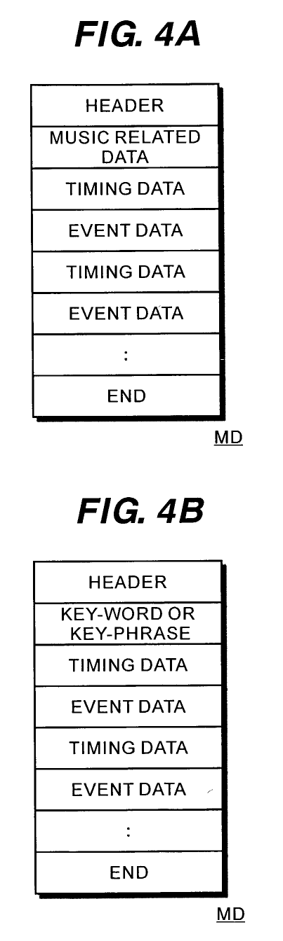

FIG. 4 are concept diagrams showing formats of the music data MD according to the embodiment of the present invention. The music data MD is, for example, an auto performance data based on a Standard MIDI File (SMF) format. Also, for example, it is an auto performance data such as a ringer melody (a ring tone with a melody) based on a simplified MIDI standard for the mobile information terminal.

FIG. 4A is an example wherein the music related data is embedded in the music data MD. The music data MD is formed of a header stored at the beginning of the data, a music related data, a timing data that represents reproducing timing and an event data that represents an event by each timing. Also, the music data MD may be formed of a plurality of parts.

The header is data for setting various reproduction modes when reproducing each part (a track), and, for example, includes tone color setting data, volume setting data and tempo setting data. The timing data is data that represents the time to process the various kinds of events represented by the event data. The processing time of the event may be represented by an absolute time from the beginning of the performance, or a relative time that is a lapse time from the preceding event. The event data represents a content of various kinds of events for reproducing a musical tone. The event includes an event directly related to a generation of a musical tone such as a note-on event and a note-off event and a set up event for setting a reproduction style of a musical tone such as a pitch-change event, a tempo-change event and a tone color-change (program change) event or the like. The music related data is the URL of the site for downloading the music related product directly, the URL of the site linked to that site, or the URL of the physical sales site of the music related product. Further, the plurality of the URLs of the sales sites each of which is different from others by the kinds of the music related products might be embedded in one music data.

Further, in this embodiment of the present invention, for convenience of an explanation, the site that enables the user to directly download the above-described music related product and the linked site or the physical sales site of the music related product are on the same product providing server 1. That is, the URL of the product providing server 1 is embedded as a music related data in the embodiment of the present invention.

FIG. 4B is an example wherein a keyword or a key phrase is embedded in the music data MD. Other structure is the similar to the music data shown in FIG. 4A. The keyword or the key phrase is used for searching a music related product or a sales page of the music related product in the product providing server 1. The keyword is, for example, a title, a performer, a composer, a lyrics writer, a whole part or a part of the lyrics, tie-up information on TV, radio and commercial film of a song represented by the music data MD. The key phrase is, for example, an introduction part, a top part of melody, a performance phrase of a motif part of the music data, or audio data corresponding to those parts. In the music data MD shown in FIG. 4B, at least one of those keywords or key phrases is embedded to the music data MD, and the electronic musical device 3 (FIG. 1) reads the keyword or the key phrase from the music data MD and transfers it to the product providing server 1. The product providing server 1 searches a sales page of the music related product by using the received keyword or key phrase and transfers the search result back to the electronic music device 3.

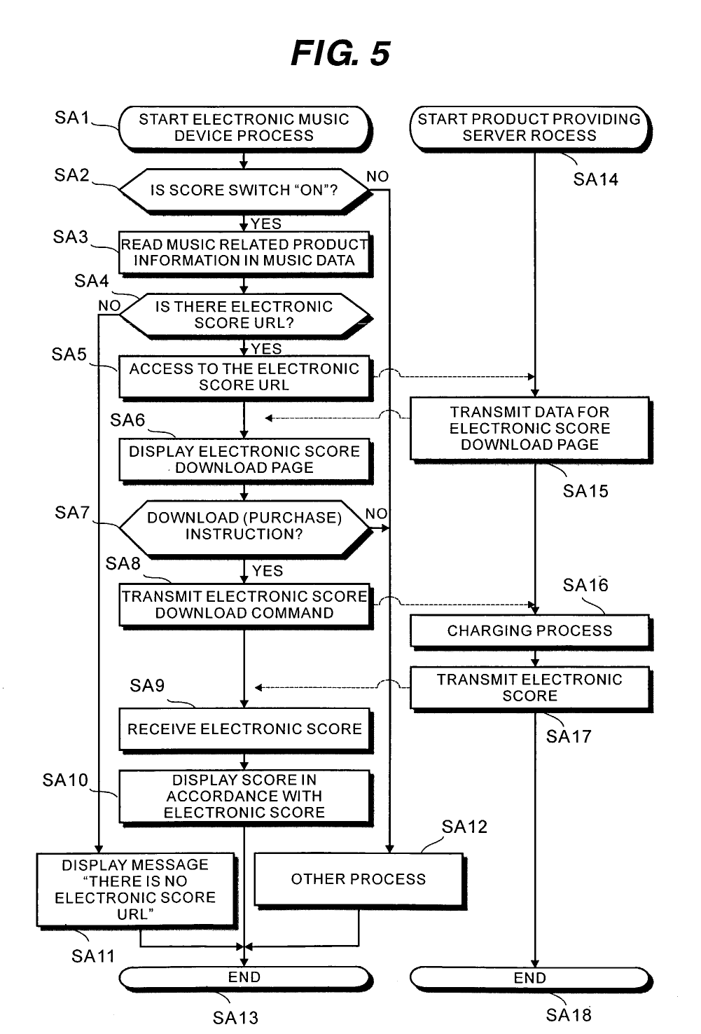

FIG. 5 is a flow chart showing a first example of purchasing and sales operations of a music related product according to the embodiment of the present invention performed by an electronic music device 3 and a product providing server 1. Dotted lines in the drawing show flows of data.

In the drawing, Steps SA1 to SA13 represent a purchasing process of the music related product performed in the electronic music device 3, and Steps SA14 to SA18 represent a sales process of the music related product performed in the product providing server 1. In this example, an electronic score of the music data is purchased and downloaded by connecting the electronic music device 3 with the product providing server 1.

At Step SA1, the purchasing process of the music related product is started, and then various kinds of flags and buffer are initialized to proceed to the next Step SA2. Further, the music related product purchasing process is booted in the state that at least one music data is loaded on the electronic music device 3. At Step SA2, whether the score switch is “ON” (manipulated) or “OFF” is judged. When the score switch is “ON”, the process proceeds to Step SA3, when it is not, other process is executed. At Step SA3, the music related data in the loaded music data is read out. At Step SA4, whether the URL (an electronic score URL) of an electronic score sales (downloading) page is contained or not in the music related data read at Step SA3 is detected. When the electronic score URL is contained, the process proceeds to Step SA5 as shown by an arrow “YES”. When the electronic score URL is not contained, the process proceeds to Step SA11 as shown by an arrow “NO”, displaying a message saying “there is not the electronic score” on the display 14 (FIG. 2) or the display 24 (FIG. 3), and then the process proceeds to Step SA13.

At Step SA5, the electronic music device 3 accesses to the electronic score URL detected at Step SA4. In this embodiment of the present invention, an electronic score downloading page is prepared in the product providing server 1, a transfer of data for the electronic score downloading page is requested by connecting to the product providing server 1. At Step SA6, the data for the electronic score downloading page transmitted from the product providing server 1 at a later-described Step SA15 is received, and the electronic score downloading page is displayed on the display 14 (FIG. 2) or the display 24 (FIG. 3). At Step SA7, an electronic score downloading (purchasing) instruction from the user is detected. When the download is instructed, the process proceeds to Step SA8, and when the download is not instructed, other process is executed. At Step SA8, a download command of the purchasing the electronic score is transmitted to the product providing server 1. At Step SA9, the electronic score transmitted from the product providing server 1 at later-described Step SA17 is received and stored in the external storage device 15 (FIG. 1, FIG. 2) or the like. At this time, the electronic score may preferably be stored with reference to the corresponding music data. At Step SA10, the score is displayed on the display 14 (FIG. 2) or the display 24 (FIG. 3) based on the electronic score received at Step SA9. At Step SA12, other process is executed. The other process is a process for purchasing a downloadable product such as the MIDI data, the audio data or the like. The purchasing process of the downloadable product is basically the same as the case of purchasing the electronic score.

At Step SA13, the music related product purchasing process in the electronic music device 3 is finished. In the case that the MIDI data and the audio data or the like other than the electronic score is downloaded (purchased), the purchased MIDI data and audio data or the like is reproduced in the part corresponding to Step SA10.

In Step SA14, the music related product sales process executed in the product providing server 1 is started, and various kinds of flags and buffer are initialized. Further, the product providing server 1 stores downloadable products such as a plurality of electronic scores, MIDI data, and audio data or the like, and also stores a database of these sales (download) pages. At Step SA15, the data for the electronic score download page is transmitted to the electronic music device 3 by responding to the access from the electronic music device 3 at Step SA5. At Step SA16, the download command of the electronic score is received, a charging process for a price of the electronic score for the user of the electronic music device 3 that transmitted the download command is executed. The charging process is executed with a well-known technique. For example, a credit card, a postal or a bank transfer and electronic money or the like are used as charging method to the user. At Step SA17, the electronic score is transmitted to the electronic music device 3 in accordance with the download command received at Step SA16. Then the process proceeds to the next Step SA18, and the music related product sales process is finished.

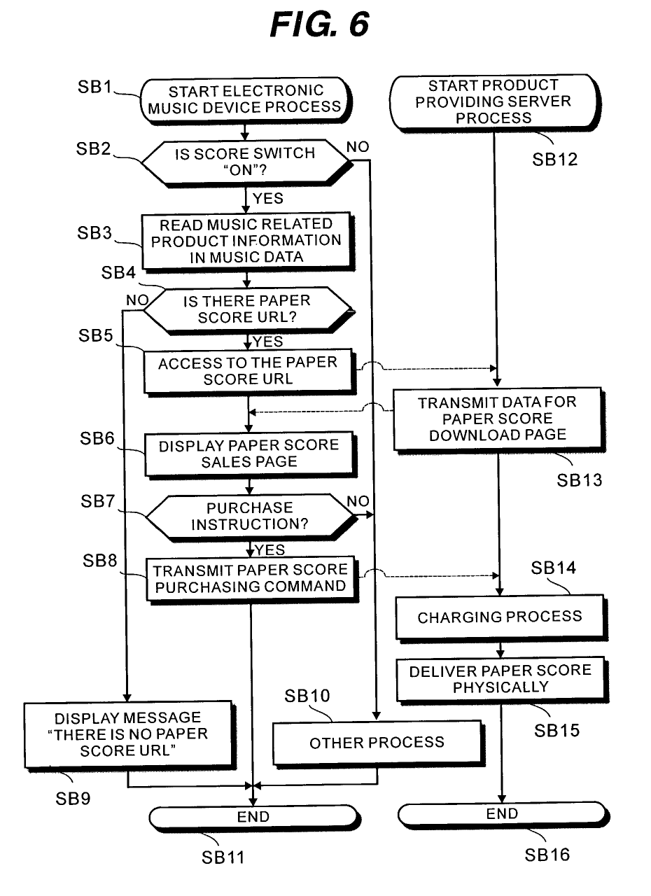

FIG. 6 is a flow chart showing a second example of purchasing and sales operations of a music related product according to the embodiment of the present invention performed by an electronic music device 3 and a product providing server 1. Dotted lines in the drawing show flows of data.

In the drawing, Step SB1 to SB11 is a purchasing process of the music related product performed in the electronic music device 3, and Step SB12 to SB16 is a sales process of the music related product performed in the product providing server 1. In this example, a paper score (a hard copy or printed music score) of the music data is purchased by connecting the electronic music device 3 to the product providing server 1.

Further, a process in Step SB1 to Step SB8 in the FIG. 6, a process at Step SB9 and processes at Step SB12 to Step SB14 are the almost same as the processes at Step SA1 to the Step SA8, the process at Step SA11 and the processes at Step SA14 to the Step SA16, and the difference between the FIG. 5 and the FIG. 6 is that the process in the FIG. 6 is concerning to the paper score although the process in the FIG. 5 is concerning to the electronic score. Therefore, the explanations for the similar processes as the explained process by using the FIG. 5 are omitted, and only different parts are explained.

The electronic music device 3 executes a process for purchasing other physical product such as a book, a lyrics card, etc. at Step SB10 as other process when the score switch is judged to be “OFF” at Step SB3. A purchasing process of the physical product is basically same as the process for purchasing the paper score. Then, at Step SB11, the music related product purchasing process executed in the electronic music device 3 is finished.

At Step SB15, the product providing server 1 executes a physical delivery process of the paper score in accordance with the purchasing command received at Step SB14, following to receiving of the purchasing command and the charging process at Step SB14. There after, the music related product sales process is finished at Step SB16.

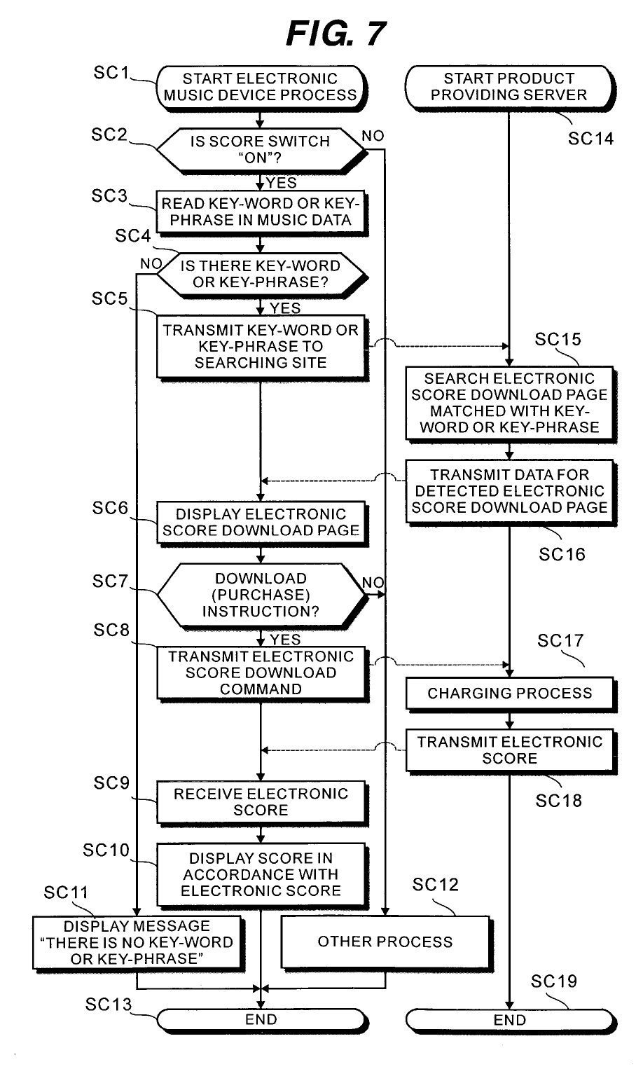

FIG. 7 is a flow chart showing a first example of purchasing and search and sales operations of a music related product according to the embodiment of the present invention performed by an electronic music device 3 and a product providing server 1. Dotted lines in the drawing show flows of data.

In the drawing, Step SC1 to SC13 is a purchasing process of the music related product performed in the electronic music device 3, and Step SC14 to SC19 is a sales process of the music related product performed in the product providing server 1. In this example, the electronic music device 3 connects to the product providing server 1 and makes the product providing server 1 search an electronic score corresponding to the music data. Then, the detected electronic score is purchased and downloaded.

In this example, although the sales page of the electronic score corresponding to the music data is displayed by using the keyword or the key phrase included in the music data, the downloadable product related to the keyword may be searched, or music data corresponding to the same kind of music as the music data may be searched by using the key phrase.

Processes at Step SC1 to Step SC2 are the same processes as at Step SA1 to Step SA2.

At Step SC3, a keyword or a key phrase embedded in the music data is read out. At Step SC4, whether the keyword or the key phrase is embedded or not is detected. When the keyword or the key phrase is embedded, the process proceeds to Step SC5 by following an arrow marked “YES”. When the keyword or the key phrase is not embedded, the process proceeds to Step SC11 following an arrow marked “NO”, displays a message saying “there is no keyword or key phrase” on the display 14 (FIG. 2) or the display 24 (FIG. 3), and then the process proceeds to Step SC13. At Step SC5, the electronic music device 3 accesses to a searching site. Because a searching page is prepared in the product providing server 1 according to this embodiment of the present invention, the electronic music device 3 is connected to the product providing server 1. The URL of the searching site may be stored in the ROM 8 of the electronic music device 3, the external storage device 15 or the like by default, or in the music data with the keyword or the key phrase.

Processes at Step SC6 to Step SC13 are the same processes as at Step SA6 to SA13.

At Step SC14, the music related product sales process executed in the product providing server 1 is started, then various kinds of flags and buffer are initialized, and the process is preceded to the next Step SC15. Further, the product providing server 1 stores downloadable products such as a plurality of electronic scores, MIDI data, audio data, etc., and also stores a database of sales (download) pages for those downloadable products.

At Step SC15, the keyword or the key-phrase is received responding to the access from the electronic music device 3 at Step SC5. Then an electronic score sales page that matches to the keyword or the key-phrase is searched. At Step SC16, data for the detected electronic score sales page that matches to the keyword or the key-phrase that is received at Step SC15 is sent to the electronic music device 3. If the electronic score sales page that matches to the received keyword or key-phrase can not be detected, the fact that there is no electronic score sales page matches to the keyword or the key-phrase is notified to the electronic music device 3.

Step SC17 is the same process as at Step SA16 in FIG. 5, and Step SC18 is the same process as at Step SA17. Then, the process proceeds to the next Step SC19, and the music related product sales process is finished.

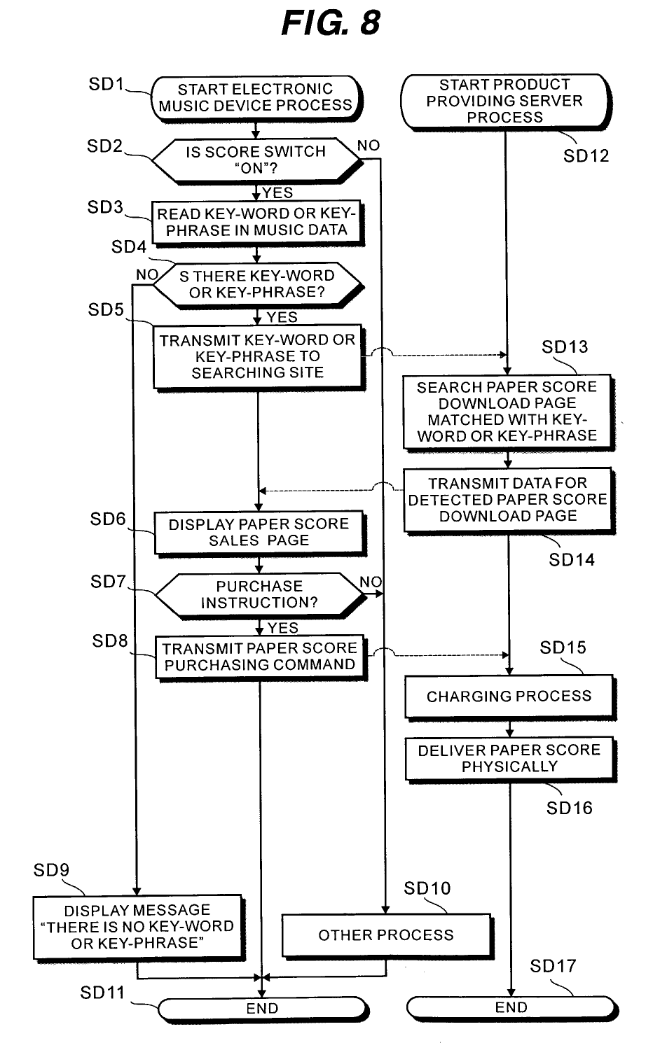

FIG. 8 is a flow chart showing a second example of purchasing and search and sales operations of a music related product according to the embodiment of the present invention performed by an electronic music device 3 and a product providing server 1. Dotted lines in the drawing show flows of data.

In the drawing, Step SD1 to SD11 is a purchasing process of the music related product performed in the electronic music device 3, and Step SD12 to SD17 is a sales process of the music related product performed in the product providing server 1. In this example, the electronic music device 3 connects to the product providing server 1 and makes the product providing server 1 search a paper score corresponding to the music data. Then, the detected paper score is purchased.

Further, processes at Step SD6 to Step SD11 in FIG. 8, processes at Step SD15 to Step SD17, processes at Step SD1 to Step SD5 and processes at Step SD12 to Step SD14 are the almost same as the processes at Step SB6 to Step SB11 in FIG. 6, the processes at Step SB14 to Step SB16 in FIG. 6, the processes at Step SC1 to Step SC5 in FIG. 7 and the processes at Step SC14 to Step SC16, and the difference between FIG. 7 and FIG. 8 is that the process in FIG. 6 is concerning to the paper score although the process in FIG. 7 is concerning to the electronic score.

As described in the above, according to the embodiment of the present invention, because the URL of the music related product sales site is embedded in the music data, the user can purchase the product by accessing to the music related product sales site easily.

Also, according to the embodiment of the present invention, because the keyword or the key-phrase for searching the music related product and the music related product sales site are embedded in the music data, the user can purchase the product only by accessing to the product providing server to access to the music related product sales site easily.

Further, the music data according to the embodiment of the present invention can be not only regular music data, but also music data for a trial. A data length of the music data for a trial is shorter than the regular music data (i.e., a performance time of the trial music data is shorter than that of the regular music data), or a sound quality is low. In this case, the regular music data sales can be promoted by embedding the URL of the regular music data sales (downloading) site in the music data for a trial.

Also, although the process of searching and sales of the music data related product is executed in the same site (the product providing server), it can be executed in different sites. Further, the URLs of a plurality of different sales sites that sell the same music related products could be embedded to the music data. That is, a plurality of the different sites that sell the same products at different prices and with different services can be existed. In that case, one of the plurality of the sales sites in the electronic music device may be chosen from the sites.

Also, when it will be possible to sell a new music related product, information about the music related product is newly embedded in the conventional music data. For example, a notification of the new product of music related data that includes new music related data is provided to the electronic music device from the sales site (the product providing server). In the electronic music device, whether there is music data corresponding to the notification or not is judged. Then if the corresponded music data is stored in the external storage device, the music related data in the notification will be embedded in the corresponding music data. Also in the case of searching the keyword or the key-phrase, from a time when the music data can be offered, an information of a new music related product sales page is registered on the searching database.

Also the product providing server distinguishes the types of the downloadable products that can handle with in the electronic music device, and only the sales page of the product that can handle with may be presented. In that case, for example, when the electronic music device accesses to the product providing server, a distinguishing information of the device (the types and kinds of the electronic music device) and the product information that can handle with are sent to the product providing server, and the product providing server judges the product types that can be handled with in the electronic music device according to the information.

Moreover, the electronic musical device 3 can be a karaoke system, a game device, an automatic performance piano, etc. other than the electronic musical instrument 3a, the client PC 3b (personal computer plus application software) and mobile communication terminal 3c such as a cellular phone according to the embodiment. When the electronic musical device 3 is the mobile communication device 3c, a combination of the terminal and a server, each having a part of the functions, can be used other than the terminal having a complete functions by itself. Also, when the electronic musical device 3 is the electronic musical instrument 3a, it can be any forms of musical instruments such as a wind instrument, s string instruments, a percussion, etc. other than the keyboard instrument.

The present invention has been described in connection with the preferred embodiments. The invention is not limited only to the above embodiments. It is apparent that various modifications, improvements, combinations, and the like can be made by those skilled in the art.

What are claimed are:

1. An electronic music apparatus, comprising:
a storage device that stores music data comprising music related data that is information for accessing to a music related product sales site on a network;
a reading device that reads the music related data from the music data;
an accessing device that accesses to the music related product sales site in accordance with the read music related data; and
a transmitter that transmits a request for purchasing a music related product to the music related product sales site.

2. An electronic music apparatus, comprising:
a storage device that stores music data comprising search information for searching a music related product;
a reading device that reads the searching information from the music data;
a first transmitter that transmits the read searching information to a music related product sales site on a network, the music related product sales site replying a search result by searching a music related product in accordance with the searching information; and
a second transmitter that transmits a request for purchasing the searched music related product.

3. A program which computer can executes for realizing a download process, the download process comprising the instructions for;
(a) reading music data from a storage device, the music data comprising music related data that is information for accessing to a music related product sales site on a network;
(b) accessing to the music related product sales site in accordance with the read music related data; and
(c) transmitting a request for purchasing a music related product to the music related product sales site.

4. A program which computer can executes for realizing a download process, the download process comprising the instructions for;
(a) reading music data from a storage device, the music data comprising search information for searching a music related product;
(b) transmitting the read searching information to a music related product sales site on a network, the music related product sales site replying a search result by searching a music related product in accordance with the searching information; and
(c) transmitting a request for purchasing the searched music related product.

5. A storage medium storing music data comprising music related data that is information for accessing to a music related product sales site on a network.

6. A storage medium storing music data comprising search information for searching a music related product in a music related product sales site on a network.
